(19) United States
(12) Patent Application Publication
(10) Pub. No.: US 2025/0176161 A1
(43) Pub. Date: May 29, 2025

(54) SEMICONDUCTOR DEVICES HAVING CHANNEL STRUCTURES

(71) Applicant: Samsung Electronics Co., Ltd., Suwon-si (KR)

(72) Inventor: Yoonhwan CHOI, Suwon-si (KR)

(73) Assignee: Samsung Electronics Co., Ltd., Suwon-si (KR)

(21) Appl. No.: 18/659,238

(22) Filed: May 9, 2024

(30) Foreign Application Priority Data
Nov. 27, 2023 (KR) 10-2023-0167066

(51) Int. Cl. H10B 12/00

(52) U.S. Cl. CPC H10B 12/315; H10B 12/05

(57) ABSTRACT

A semiconductor device may include a bit line extending in a first horizontal direction, a mold structure on the bit line, a channel structure including a horizontal portion in contact with an upper surface of the bit line and a vertical channel portion extending upwardly from one end of the horizontal portion, a gate electrode on the channel structure, and a landing pad structure on the vertical channel portion and electrically connected to the channel structure. The vertical channel portion may be in contact with a side surface of the mold structure. At least a portion of the vertical channel portion may overlap the mold structure in a second horizontal direction. The second direction may intersect the first horizontal direction.

### CROSS-REFERENCE TO RELATED APPLICATION(S)

This application claims the benefit under 35 USC 119(a) of Korean Patent Application No. 10-2023-0167066 filed on Nov. 27, 2023 in the Korean Intellectual Property Office, the entire disclosure of which is incorporated herein by reference for all purposes.

### BACKGROUND

Inventive concepts relate to semiconductor devices having channel structures.

As demand for high performance, high speed, and/or multifunctionality in semiconductor devices increases, the degree of integration of semiconductor devices is increasing. In manufacturing fine-patterned semiconductor devices in response to the trend for high integration of semiconductor devices, it is necessary to implement patterns with fine widths or fine spacing.

### SUMMARY

Example embodiments provide a semiconductor device including a channel structure in contact with a protrusion or a recess of a mold structure.

According to example embodiments, a semiconductor device may include a bit line extending in a first horizontal direction; a mold structure on the bit line; a channel structure including a horizontal portion in contact with an upper surface of the bit line and a vertical channel portion extending upwardly from one end of the horizontal portion; a gate electrode on the channel structure; and a landing pad structure on the vertical channel portion and electrically connected to the channel structure. The vertical channel portion may be in contact with a side surface of the mold structure. At least a portion of the vertical channel portion may overlap the mold structure in a second horizontal direction. The second horizontal direction may intersect the first horizontal direction.

According to example embodiments, a semiconductor device may include a bit line extending in a first horizontal direction; a mold structure on the bit line and extending in a second horizontal direction, the second horizontal direction intersecting the first horizontal direction; channel structures including horizontal portions in contact with an upper surface of the bit line and vertical channel portions extending upwardly from one ends of the horizontal portions; a gate electrode on the channel structures; and landing pad structures on the vertical channel portions and electrically connected to the channel structures. The mold structure may include first portions and second portions alternately disposed in the second horizontal direction. Lower surfaces of the first portions of the mold structure may have a first horizontal width in the first horizontal direction. Lower surfaces of the second portions of the mold structure may have a second horizontal width in the first horizontal direction. The second width may be different from the first horizontal width. The vertical channel portions may be spaced apart from each other in the second horizontal direction. The vertical channel portions may contact a side surface of the mold structure.

According to example embodiments, a semiconductor device may include a lower structure including a circuit element; a bit line on the lower structure and extending in a first horizontal direction; a mold structure on the bit line and extending in a second horizontal direction, intersecting the first horizontal direction; channel structures including horizontal portions in contact with an upper surface of the bit line and vertical channel portions extending upwardly from one ends of the horizontal portions; a gate electrode on the channel structures; a dielectric structure extending between the channel structures and the gate electrode in the second horizontal direction; an upper insulating structure spaced apart from the mold structure and covering the gate electrode and the bit line; an upper capping layer covering the mold structure and the upper insulating structure; landing pad structures penetrating through the upper capping layer and electrically connecting to the channel structures; and an information storage structure on the landing pad structures. The vertical channel portions may contact a side surface of the mold structure. At least a portion of the vertical channel portions may overlap the mold structure in the second horizontal direction.

### BRIEF DESCRIPTION OF DRAWINGS

The above and other aspects, features, and advantages of embodiments of inventive concepts will be more clearly understood from the following detailed description, taken in conjunction with the accompanying drawings, in which:

FIG. 1A is a plan view of a semiconductor device according to an example embodiment;

FIG. 1B is a vertical cross-sectional view taken along line I-I′ of the semiconductor device illustrated in FIG. 1A;

FIG. 1C is a vertical cross-sectional view taken along line II-II′ of the semiconductor device illustrated in FIG. 1A;

FIG. 1D is a vertical cross-sectional view taken along line III-III′ of the semiconductor device illustrated in FIG. 1A;

FIG. 2 is an enlarged view of a portion of the semiconductor device illustrated in FIG. 1A;

FIGS. 3 to 5 are plan views of semiconductor devices according to example embodiments;

FIG. 6 is a plan view of a semiconductor device according to an example embodiment;

FIG. 7 is an enlarged view of a portion of the semiconductor device illustrated in FIG. 6;

FIGS. 8 to 10 are plan views of semiconductor devices according to example embodiments; and

FIGS. 11A to 15D are plan views and vertical cross-sectional views illustrated according to a process sequence, illustrating a method of manufacturing a semiconductor device according to an example embodiment.

### DETAILED DESCRIPTION

Hereinafter, Example Embodiments Will be Described with Reference to the Accompanying Drawings.

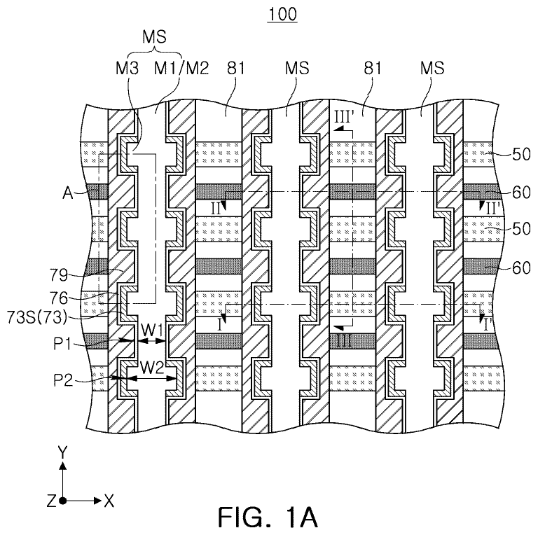

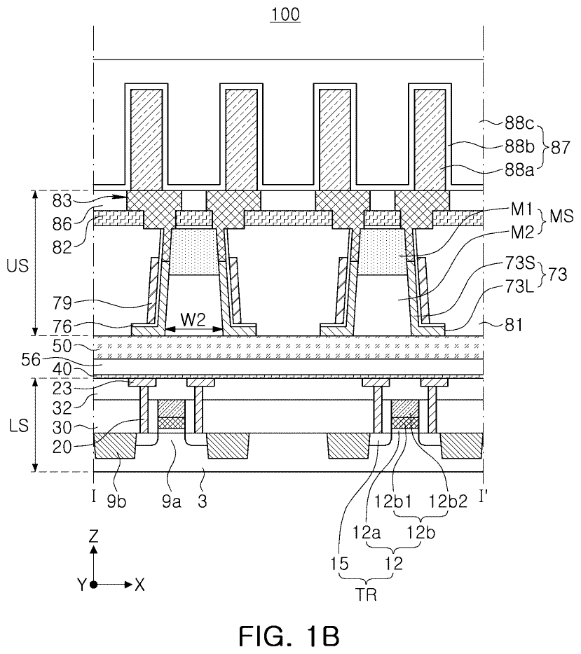

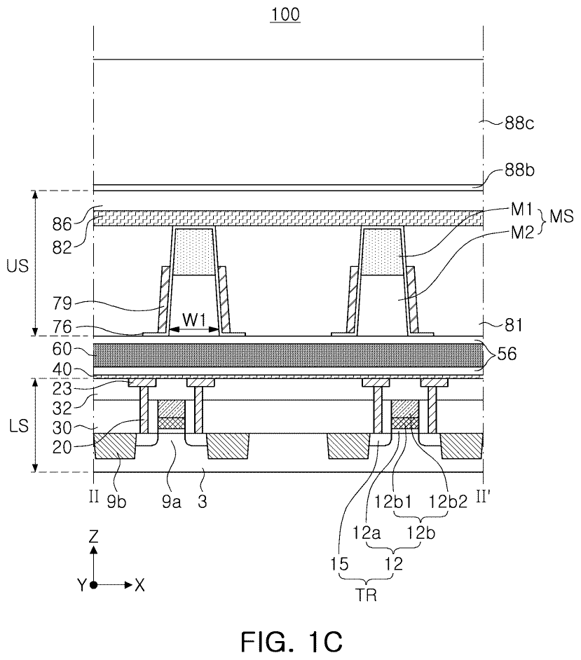

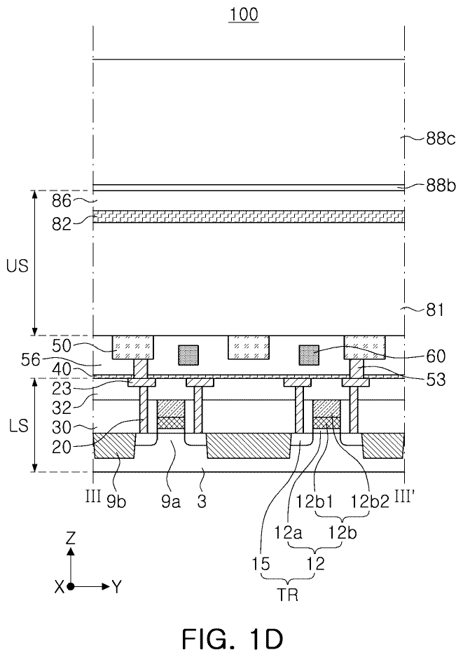

FIG. 1A is a plan view of a semiconductor device according to an example embodiment. FIG. 1B is a vertical cross-sectional view taken along line I-I′ of the semiconductor device illustrated in FIG. 1A. FIG. 1C is a vertical cross-sectional view taken along line II-II′ of the semiconductor device illustrated in FIG. 1A. FIG. 1D is a vertical cross-sectional view taken along line III-III′ of the semiconductor device illustrated in FIG. 1A.

Referring to FIGS. 1A to 1D, a semiconductor device 100 according to an example embodiment may include a lower structure LS, a bit line 50, an upper structure US, and an information storage structure 87. The lower structure LS may include a substrate 3, a circuit element TR, a peripheral plug 20, a peripheral interconnection 23, a first peripheral insulating layer 30, and a second peripheral insulating layer 32.

The substrate 3 may include a semiconductor material, such as a group IV semiconductor, a group III-V compound semiconductor, or a group II-VI compound semiconductor. For example, a group IV semiconductor may include silicon, germanium, or silicon-germanium. The substrate 3 may be a silicon substrate, a silicon-on-insulator (SOI) substrate, a germanium substrate, a germanium-on-insulator (GOI) substrate, a silicon-germanium substrate, or a substrate including an epitaxial layer.

The circuit element TR may include a word line driver, a sense amplifier, row and column decoders, and control circuits. The circuit element TR may include a peripheral transistor. For example, the peripheral transistor may include a gate structure 12 disposed on the peripheral active region 9a defined by the isolation region 9b in the substrate 3, and peripheral source/drain regions 15 disposed within the peripheral active region 9a on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 on the first conductive layer 12b1.

The peripheral plug 20 is connected to the peripheral source/drain region 15 and may extend vertically, and the peripheral interconnection 23 may be disposed on the peripheral plug 20. The peripheral interconnection 23 may be electrically connected to the circuit element TR through the peripheral plug 20. The first peripheral insulating layer 30 may surround the side surfaces of the peripheral gate electrode 12b and the peripheral plug 20. The second peripheral insulating layer 32 may be disposed on the first peripheral insulating layer 30 and may surround the peripheral plug 20 and the peripheral interconnection 23. The upper surface of the second peripheral insulating layer 32 may be coplanar with the upper surface of the peripheral interconnection 23.

In an example embodiment, the peripheral plug 20 and the peripheral interconnection 23 may include a metal layer and a barrier layer covering side and low surfaces of the metal layer. The barrier layer may include at least one of TiN, TaN, WN, TiSiN, TaSiN, or RuTiN, and the metal layer may include a metal material such as W or Mo. The first peripheral insulating layer 30 and the second peripheral insulating layer 32 may include silicon oxide, silicon nitride, silicon oxynitride, low dielectric constant, or combinations thereof.

The semiconductor device 100 may further include an etch stop layer 40 disposed on the lower structure LS. The etch stop layer 40 may cover the peripheral interconnection 23 and the second peripheral insulating layer 32. The etch stop layer 40 may include SiBN, SiCN, SiN, or combinations thereof.

The bit line 50 may be disposed on the lower structure LS. The bit lines 50 may extend in the X-direction and may be spaced apart from each other in the Y-direction. The semiconductor device 100 may further include a bit line plug 53 disposed below the bit line 50 and a bit line insulating layer 56 surrounding the bit line 50 and the bit line plug 53. The bit line 50 may be electrically connected to the lower structure LS through the bit line plug 53.

The bit line 50 may include a metal layer and a barrier layer covering side and low surfaces of the metal layer. The barrier layer may include at least one of TiN, TaN, WN, TiSiN, TaSiN, or RuTiN, and the metal layer may include a metal material such as W or Mo. The bit line plug 53 may include the same material as the peripheral plug 20 and the peripheral interconnection 23. The bit line insulating layer 56 may include silicon oxide, silicon nitride, silicon oxynitride, low dielectric constant, or combinations thereof.

The semiconductor device 100 may further include shield patterns 60 that extend in the X-direction and are spaced apart from each other in the Y-direction. The shield patterns 60 may be arranged alternately with the bit lines 50 in the Y-direction. The lower surface of the shield pattern 60 may be located at a lower level than the lower surface of the bit line 50, and the upper surface of the shield pattern 60 may be located at a lower level than the upper surface of the bit line 50. The shield patterns 60 may reduce capacitance between bit lines 50.

The shield pattern 60 may include doped polysilicon, metal, conductive metal nitride, metal-semiconductor compound, metal compound, conductive metal oxide, graphene, carbon nanotube, or combinations thereof.

The upper structure US may be disposed on the bit line 50. The upper structure US may include a mold structure MS, a channel structure 73, a gate electrode 79, an upper insulating structure 81, an upper capping layer 82, and a landing pad structure 83.

The mold structure MS may be disposed on the bit line 50. In plan view, the mold structures MS may extend in the Y-direction and may be spaced apart from each other in the X-direction. The mold structure MS may include a lower mold layer M2 and an upper mold layer M1. The upper mold layer M1 may be disposed on the lower mold layer M2, and the lower mold layer M2 and the upper mold layer M1 may extend in the Y-direction.

In an example embodiment, the mold structure MS may further include protrusions M3. The protrusions M3 may protrude in the X-direction from both sides of the mold structure MS. For example, the protrusions M3 may be spaced apart from each other in the X and Y-directions and may be disposed with the lower mold layer M2 and the upper mold layer M1 interposed therebetween. In an example embodiment, the mold structure MS may include a first portion P1 and a second portion P2 arranged with the first portion P1 in the Y-direction. The first portion P1 and the second portion P2 may be alternately arranged in the Y-direction. For example, a portion of the mold structure MS that does not include the protrusion M3 may be referred to as the first portion P1, and a portion of the mold structure MS including the protrusion M3 may be referred to as the second portion P2. The first portion P1 may have a first width W1 in the X-direction, and the second portion P2 may have a second width W2 that is larger than the first width W1. In this case, the first width W1 and the second width W2 may refer to the horizontal width of the lower surface of the mold structure MS.

The lower mold layer M2 and the upper mold layer M1 may include silicon oxide, silicon nitride, silicon oxynitride, or combinations thereof. In an example embodiment, the lower mold layer M2 and the upper mold layer M1 may include different materials. For example, the lower mold layer M2 may include silicon oxide, and the upper mold layer M1 may include silicon nitride. The protrusion M3 may include the same material as the lower mold layer M2 and the upper mold layer M1 and may be materially continuous. For example, the lower portion of the protrusion M3 may extend in the X-direction from the side of the lower mold layer M2 and may include the same material as the lower mold layer M2. The upper portion of the protrusion M3 may extend in the X-direction from the side of the upper mold layer M1 and may include the same material as the upper mold layer M1.

The channel structure 73 may be disposed on the bit line 50. The channel structure 73 may include a horizontal portion 73L that contacts and is electrically connected to the bit line 50, and a vertical channel portion 73S extending upwardly from one end of the horizontal portion 73L in the X-direction. The lower surface of the horizontal portion 73L may be in contact with the bit line 50, and the horizontal portion 73L may be electrically connected to the bit line 50. In an example embodiment, the vertical channel portion 73S may extend in a direction oblique to the vertical direction (Z-direction), but is not limited thereto. The channel structures 73 may be spaced apart from each other in the X and Y-directions.

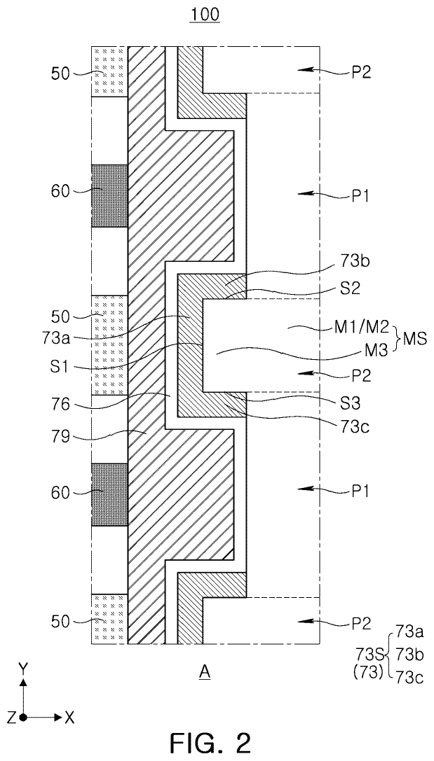

FIG. 2 is an enlarged view of a portion of the semiconductor device illustrated in FIG. 1A.

Referring further to FIG. 2, the channel structure 73 may be in contact with the protrusion M3. The channel structure 73 may contact the side surface of the second portion P2 of the mold structure MS and may partially contact the side surface of the first portion P1. For example, the vertical channel portion 73S of the channel structure 73 may surround the outer side surface of the protrusion M3. For example, a portion of the vertical channel portion 73S of the channel structure 73 may overlap the protrusion M3 in the Y-direction.

The vertical channel portion 73S of the channel structure 73 may include an extension portion 73a, a first bent portion 73b, and a second bent portion 73c. The extension portion 73a may extend in the Y-direction, and the first bent portion 73b and the second bent portion 73c are disposed at both ends of the extension portion 73a and may extend in a direction intersecting the Y-direction. In an example embodiment, the first bent portion 73b and the second bent portion 73c may extend in the X-direction and overlap the protrusion M3 in the Y-direction.

The vertical channel portion 73S may include a first side S1 perpendicular to the X-direction, and a second side S2 and a third side S3 disposed on both sides of the first side S1. The first side S1, the second side S2, and the third side S3 may contact the protrusion M3. The second side S2 and the third side S3 may face each other and meet at an angle with the first side S1. In FIG. 2, the angle between the first side S1 and the second side S2 and the angle between the first side S1 and the third side S3 are illustrated as 90 degrees, but are not limited thereto. Depending on the example embodiment, the shape of the protrusion M3 and the shape of the vertical channel portion 73S may vary. In some embodiments, protrusion M3 and vertical channel portion 73S may have rounded sides.

In FIG. 1B, the channel structures 73 are illustrated to be spaced apart from each other in the X-direction between the mold structures MS, but example embodiments are not limited thereto. In some embodiments, the horizontal portions 73L of the adjacent and opposing channel structures 73 in the X-direction may extend in the horizontal direction and be integrally formed.

The channel structure 73 may be formed of a semiconductor material such as silicon. The channel structure 73 may be formed of single crystal silicon or polysilicon. However, the channel structure 73 is not limited to semiconductor materials such as silicon, and may be formed of other semiconductor materials that may be used as a channel region of a transistor. For example, the channel structure 73 may include an oxide semiconductor layer or a two-dimensional material layer that may be used as a channel region of a transistor.

The oxide semiconductor layer may be indium gallium zinc oxide (IGZO). However, the example embodiment is not limited thereto. For example, the oxide semiconductor layer may include at least one of Indium Tungsten Oxide (IWO), Indium Tin Gallium Oxide (ITGO), Indium Aluminum Zinc Oxide (IAGO), Indium Gallium Oxide (IGO), Indium Tin Zinc Oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO)), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The two-dimensional material layer may include at least one of a Transition Metal Dichalcogenide (TMD) material layer, a black phosphorous material layer, and a hexagonal Boron-Nitride (Hbn) material layer that may have semiconductor properties. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, MXene, and Janus 2D materials, capable of forming two-dimensional materials.

When viewed in plan view, the gate electrodes 79 may intersect the bit lines 50. For example, the gate electrodes 79 may extend in the Y-direction in the side surfaces of the mold structures MS and may be spaced apart from each other in the X-direction. The gate electrode 79 may be disposed on channel structure 73. For example, the gate electrode 79 may overlap the horizontal portion 73L of the channel structure 73 in the vertical direction. An upper end of the gate electrode 79 may be located at a lower level than the upper surface of the mold structure MS. At least one of the gate electrodes 79 may be a cell gate electrode or a word line.

The upper structure US may further include dielectric structures 76 between the gate electrodes 79 and the channel structure 73. The dielectric structures 76 may be disposed between the gate electrode 79 and the vertical channel portion 73S, and between the gate electrode 79 and the horizontal portion 73L. In an example embodiment, a portion of the dielectric structure 76 may cover the upper surface of the upper mold layer M1, but is not limited thereto.

In an example, each of the dielectric structures 76 may be a tunnel dielectric layer that does not include an information storage layer. For example, each of the dielectric structures 76 may include at least one of silicon oxide and high-k dielectric. The high dielectric material may include metal oxide or metal oxynitride. For example, the high dielectric may be formed of HfO₂, HfSiO, HfSiON, HfTaO, HfTiO, HfZrO, ZrO₂, Al₂O₃, or combinations thereof, but is not limited thereto. Each of the dielectric structures 76 may be formed of a single layer or multiple layers of the materials described above.

In another example, each of the dielectric structures 76 may include an information storage layer and a dielectric layer. For example, each of the dielectric structures 76 may have polarization characteristics depending on the electric field, and may include a ferroelectric layer that may have remnant polarization due to dipoles even in the absence of an external electric field. Data may be recorded using the polarization state within the ferroelectric layer. Accordingly, each of the dielectric structures 76 may include a ferroelectric layer, which may be referred to as an information storage layer. The ferroelectric layer, which may be the information storage layer, may include an Hf-based compound, a Zr-based compound, and/or an Hf—Zr-based compound. For example, the Hf-based compound may be a ferroelectric material based on HfO, Zr-based compounds may include ZrO-based ferroelectric materials, and the Hf—Zr-based compound may include a ferroelectric material based on hafnium zirconium oxide (HZO). The ferroelectric layer, which may be the information storage layer, may include a ferroelectric material doped with impurities, such as at least one of C, Si, Mg, Al, Y, N, Ge and Sn, Gd, La, Sc and Sr. For example, the ferroelectric layer, which may be the information storage layer, may be a material in which at least one of HfO₂, ZrO₂ and HZrO is doped with at least one of impurities, C, Si, Mg, Al, Y, N, Ge, Sn, Gd, La, Sc, and Sr.

In the dielectric structures 76, the information storage layer is not limited to the above-described material types and may include a material capable of storing information.

The upper insulating structure 81 may be disposed between the mold structures MS and may cover the gate electrodes 79. The upper insulating structures 81 may extend in the Y-direction and may be spaced apart from each other in the X-direction. The upper insulating structures 81 may be arranged alternately with the mold structures MS in the X-direction.

The upper insulating structure 81 may include silicon oxide, silicon nitride, silicon oxynitride, low dielectric constant, or combinations thereof. The upper insulating structure 81 may be composed of a single layer or multiple layers.

The upper capping layer 82 may cover the mold structure MS and the upper insulating structure 81 and may extend in the horizontal direction. The upper capping layer 82 may contact the upper surface of the dielectric structure 76 and the upper surface of the upper insulating structure 81. The upper capping layer 82 may include silicon nitride.

The landing pad structure 83 may be disposed on the channel structure 73 and may penetrate the upper capping layer 82 and contact the vertical channel portion 73S of the channel structure 73. For example, a portion of the landing pad structure 83 may extend below the upper capping layer 82 and contact the vertical channel portion 73S of the channel structure 73. The lower end of the landing pad structure 83 may be located at a lower level than the upper surface of the mold structure MS. The landing pad structure 83 may be electrically connected to the bit line 50 through the channel structure 73.

The landing pad structure 83 may include metal nitride, metal, or combinations thereof. The metal nitride may include at least one of TiN, TaN, WN, TiSiN, TaSiN, or RuTiN, and the metal layer may include a metal material such as W or Mo.

The upper structure US may further include insulating patterns 86 disposed on the upper capping layer 82 and between the landing pad structures 83. The insulating pattern 86 may cover the side surface of the landing pad structure 83 and electrically insulate the landing pad structures 83 from each other. The insulating pattern 86 may include silicon oxide, silicon nitride, silicon oxynitride, low dielectric constant, or combinations thereof. For example, the insulating pattern 86 may include silicon oxide.

The information storage structure 87 may be disposed on the upper structure US. The information storage structure 87 may include first electrodes 88a electrically connected to and in contact with the landing pad structures 83, a second electrode 88c on the first electrodes 88a, and a dielectric layer 88b between the first electrodes 88a and the second electrode 88c.

In an example, the information storage structure 87 may be a capacitor that stores information in DRAM. For example, the dielectric layer 88b of the information storage structure 87 may be a capacitor dielectric layer of DRAM, and the dielectric layer 87b may include a high dielectric material, silicon oxide, silicon nitride, silicon oxynitride, or combinations thereof.

In another example, the information storage structure 87 may be a structure that stores information of a memory other than DRAM. For example, the information storage structure 87 may be a capacitor of a ferroelectric memory (FeRAM). For example, the dielectric layer 88b may be a ferroelectric layer capable of recording data using a polarization state. In another example, the dielectric layer 88b may include a lower dielectric layer and a ferroelectric layer on the lower dielectric layer. In this case, the lower dielectric layer may include at least one of silicon oxide, silicon oxynitride, silicon nitride, and high-k dielectric.

In an example embodiment, if the dielectric structures 76 include an information storage layer, the information storage structure 87 may be omitted.

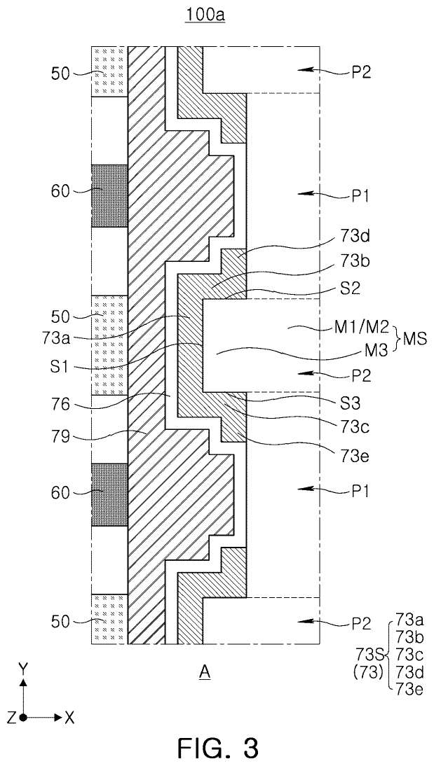

FIGS. 3 to 5 are plan views of a semiconductor device according to an example embodiment.

Referring to FIG. 3, a semiconductor device 100a may include a vertical channel portion 73S of the channel structure 73 disposed on the side of the mold structure MS and contacting the protrusion M3. In an example embodiment, the vertical channel portion 73S of the channel structure 73 may include ends extending in the Y-direction in the side of the mold structure MS. For example, vertical channel portion 73S of channel structure 73 may include an extension portion 73a, a first bent portion 73b, a second bent portion 73c, a first end 73d, and a second end 73e. The first end 73d and the second end 73e may extend in the Y-direction from one end of the first bent portion 73b and the second bent portion 73c, respectively. The first end 73d and the second end 73e may be in contact with the first portion P1 of the mold structure MS and may overlap the protrusion M3, which is part of the second portion P2, in the Y-direction.

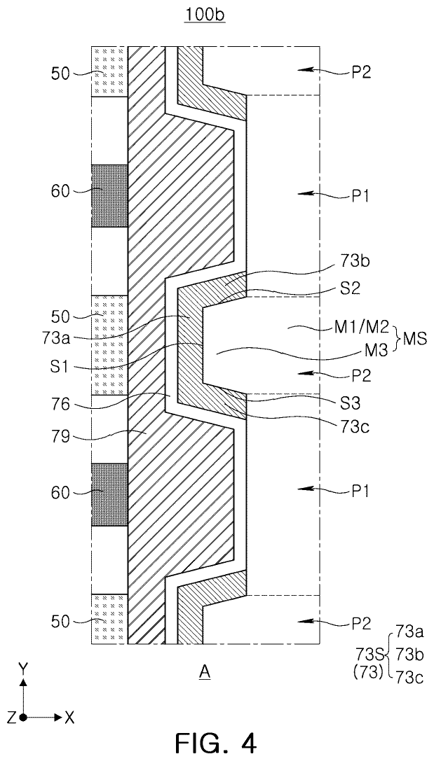

Referring to FIG. 4, a semiconductor device 100b may include a vertical channel portion 73S of the channel structure 73 disposed on the side of the mold structure MS and contacting the protrusion M3. In an example embodiment, the protrusion M3 may have a tapered shape in which the horizontal width of the protrusion M3 in the Y-direction decreases as the distance from the central axis of the mold structure MS extending in the Y-direction increases. For example, the protrusion M3 may have a trapezoidal shape in plan view. The vertical channel portion 73S of the channel structure 73 may include an extension portion 73a, a first bent portion 73b, and a second bent portion 73c, and the first bent portion 73b and the second bent portion 73c may extend in a direction between the X-direction and the Y-direction.

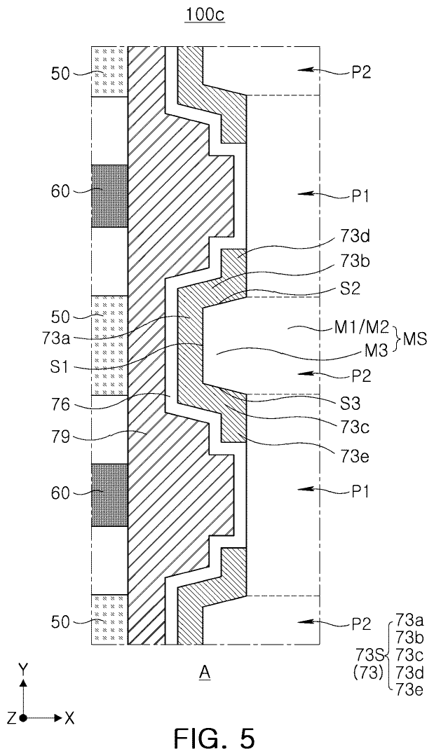

Referring to FIG. 5, a semiconductor device 100c may include a vertical channel portion 73S of the channel structure 73 disposed on the side of the mold structure MS and in contact with the protrusion M3. In an example embodiment, the vertical channel portion 73S of the channel structure 73 may include ends extending in the Y-direction in the side of the mold structure MS. Additionally, in an example embodiment, the protrusion M3 may have a tapered shape in which the horizontal width in the Y-direction of the protrusion M3 decreases as the distance from the central axis of the mold structure MS extending in the Y-direction increases. For example, the vertical channel portion 73S of channel structure 73 may include a first end 73d and a second end 73e extending in the Y-direction from one end of the first bent portion 73b and the second bent portion 73c, respectively.

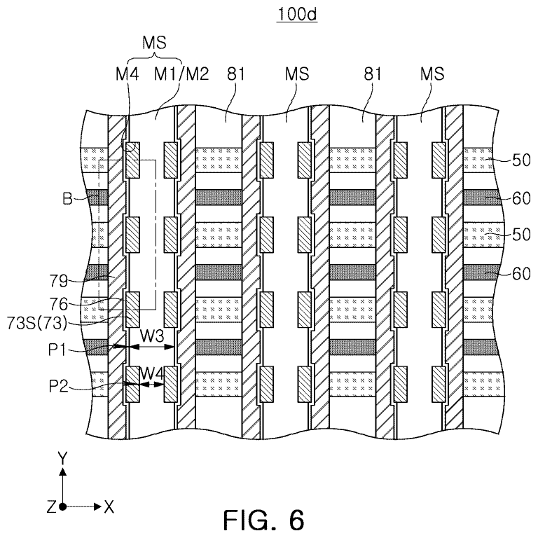

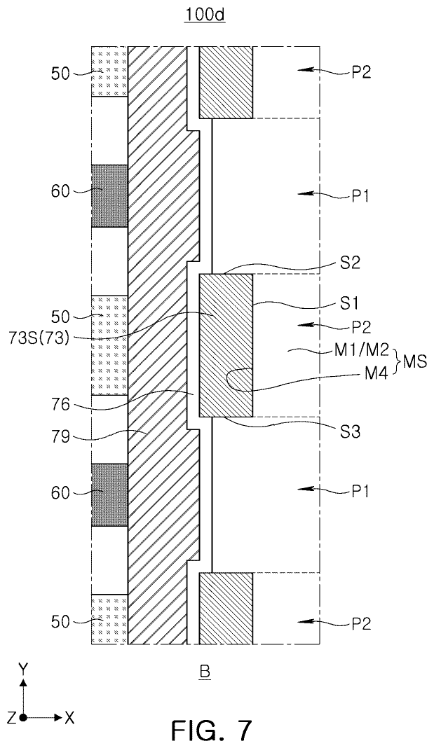

FIG. 6 is a plan view of a semiconductor device according to an example embodiment. FIG. 7 is an enlarged view of a portion of the semiconductor device illustrated in FIG. 6.

Referring to FIGS. 6 and 7, a mold structure MS of a semiconductor device 100d may include a recess portion M4 on a side surface. The recess portions M4 may be disposed on both sides of the mold structure MS, and both sides of the mold structure MS may be recessed in the X-direction. For example, the recess portions M4 may be spaced apart from each other in the X and Y-directions and may be disposed with the lower mold layer M2 and the upper mold layer M1 therebetween. In an example embodiment, the mold structure MS may include a first portion P1 and a second portion P2 arranged with the first portion P1 in the Y-direction. The first portion P1 and the second portion P2 may be alternately arranged in the Y-direction. For example, a portion of the mold structure MS that does not include the recess portion M4 may be referred to as the first portion P1, and a portion of the mold structure MS including the recess portion M4 may be referred to as the second portion P2. The width W3 of the first portion P1 in the X-direction may be greater than the width W4 of the second portion P2 in the X-direction. In this case, the width W3 and W4 may refer to the horizontal width of the lower surface of the mold structure MS.

The vertical channel portion 73S of the channel structure 73 may contact the recess portion M4. The channel structure 73 may be in contact with the side of the second portion P2 of the mold structure MS and may be partially in contact with the first portion P1. For example, a portion of the vertical channel portion 73S of the channel structure 73 may be disposed within the recess portion M4. For example, the vertical channel portion 73S may fill the recess portion M4 and may protrude in the X-direction from the side of the first portion P1. A portion of the vertical channel portion 73S of the channel structure 73 may overlap the mold structure MS in the Y-direction.

In plan view, the vertical channel portion 73S of the channel structure 73 may have a rectangular shape. However, the shape and structure of the vertical channel portion 73S are illustrative and not limited thereto.

The vertical channel portion 73S may include a first side S1 perpendicular to the X-direction, and a second side S2 and a third side S3 disposed on both sides of the first side S1. The first side S1, the second side S2, and the third side S3 may be in contact with the recess portion M4. The second side S2 and the third side S3 may face each other and meet at an angle with the first side S1. In FIG. 7, the angle between the first side S1 and the second side S2 and the angle between the first side S1 and the third side S3 are illustrated as 90 degrees, but are not limited thereto. Depending on the example embodiment, the shape of the recess portion M4 and the shape of the vertical channel portion 73S may vary. In some embodiments, protrusion M3 and vertical channel portion 73S may have rounded sides.

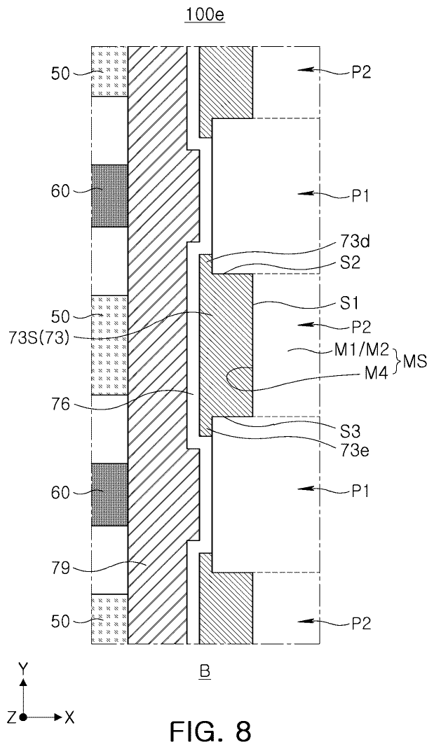

FIGS. 8 to 10 are plan views of semiconductor devices according to example embodiments.

Referring to FIG. 8, a semiconductor device 100e may include a vertical channel portion 73S of the channel structure 73 disposed on the side of the mold structure MS and contacting the recess portion M4. In an example embodiment, the vertical channel portion 73S of the channel structure 73 may include ends extending in the Y-direction in the side of the mold structure MS. For example, vertical channel portion 73S of channel structure 73 may include a first end 73d and a second end 73e. The first end 73d and the second end 73e may be in contact with the first portion P1 of the mold structure MS, and may not overlap with the mold structure MS, which is part of the second portion P2, in the Y-direction.

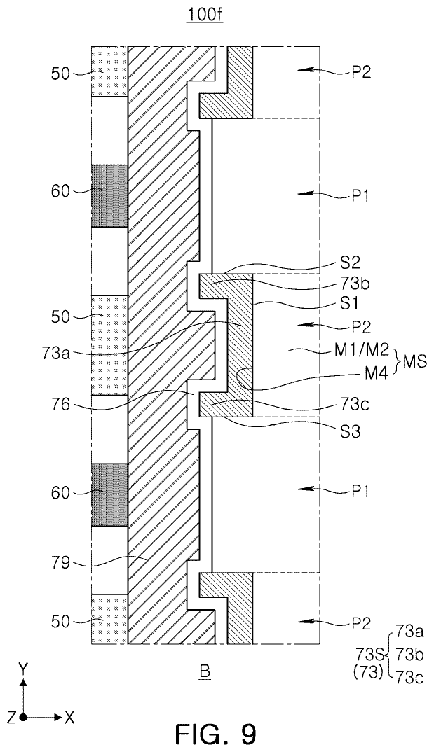

Referring to FIG. 9, a semiconductor device 100f may include a vertical channel portion 73S of the channel structure 73 disposed on the side of the mold structure MS and contacting the recess portion M4. In an example embodiment, vertical channel portion 73S may not completely fill recess portion M4, and a portion of dielectric structure 76 may be disposed within recess portion M4. For example, the vertical channel portion 73S of the channel structure 73 may include an extension portion 73a, a first bent portion 73b, and a second bent portion 73c. The extension portion 73a may extend in the Y-direction, and the first bent portion 73b and the second bent portion 73c may be disposed on both ends of the extension portion 73a and extend in a direction intersecting the Y-direction. In an example embodiment, the first bent portion 73b and the second bent portion 73c may extend in the X-direction, but are not limited thereto. In some embodiments, the first bent portion 73b and the second bent portion 73c may extend in a direction between the X-direction and the Y-direction.

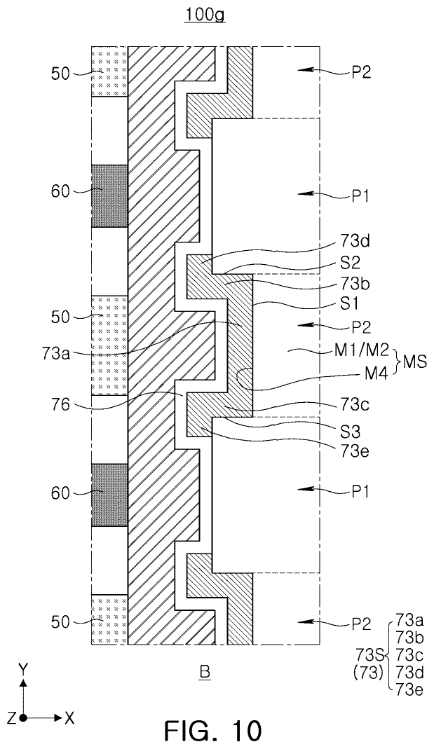

Referring to FIG. 10, a semiconductor device 100g may include a vertical channel portion 73S of the channel structure 73 disposed on the side of the mold structure MS and contacting the recess portion M4. In an example embodiment, the vertical channel portion 73S of the channel structure 73 may include ends extending in the Y-direction in the side of the mold structure MS. Additionally, in an example embodiment, vertical channel portion 73S may not completely fill recess portion M4, and a portion of dielectric structure 76 may be disposed within recess portion M4. For example, the vertical channel portion 73S of the channel structure 73 may include a first end 73d and a second end 73e.

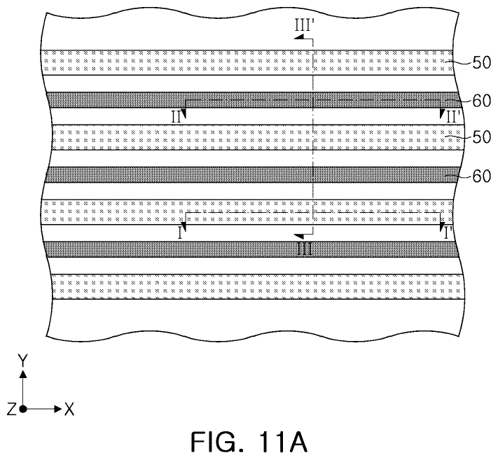

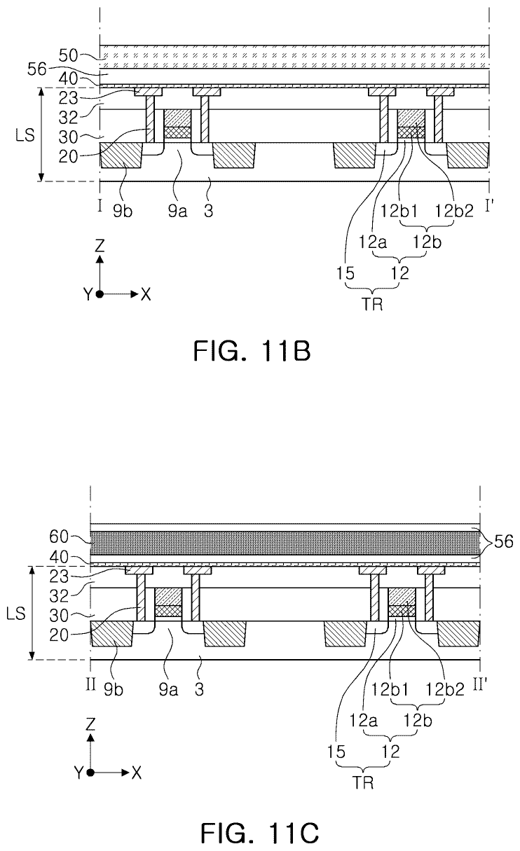

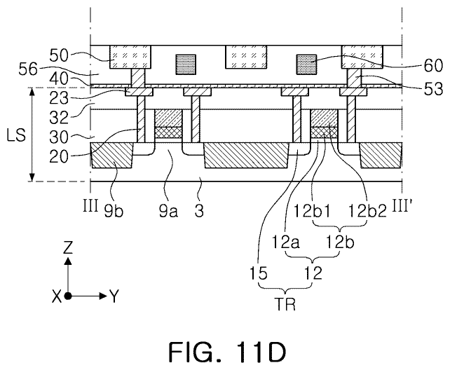

FIGS. 11A to 15D are plan views and vertical cross-sectional views illustrated according to the process sequence, illustrating a method of manufacturing a semiconductor device according to an example embodiment.

In detail, FIGS. 11A, 12A, 13A, 14A, and 15A are plan views corresponding to FIG. 1A. FIGS. 11B, 12B, 13B, 14B and 15B are vertical cross-sectional views corresponding to FIG. 1B. FIGS. 11C, 12C, 13C and 15C are vertical cross-sectional views corresponding to FIG. 1C. FIGS. 11D, 13D, 14C and 15D are vertical cross-sectional views corresponding to FIG. 1D.

Referring to FIGS. 11A to 11D, a lower structure LS may be formed. The lower structure LS may include the substrate 3 as described with reference to FIGS. 1B to 1D, the circuit element TR on the substrate 3, a peripheral interconnection 23 and a peripheral plug 20 electrically connected to the circuit element TR, a first peripheral insulating layer 30 surrounding the side of the peripheral plug 20 and the side of the circuit element TR, and a second peripheral insulating layer 32 surrounding the peripheral interconnection 23 and the peripheral plug 20.

An etch stop layer 40 may be formed on the lower structure LS. The etch stop layer 40 may cover the peripheral interconnection 23 and the second peripheral insulating layer 32.

A bit line 50, a bit line plug 53, a bit line insulating layer 56, and a shield pattern 60 may be formed on the etch stop layer 40. For example, the bit line plug 53 may be formed to penetrate the etch stop layer 40 and contact the peripheral interconnection 23, and the bit line 50 may be formed on the bit line plug 53. An insulating material may be deposited to cover the bit line plug 53 and the bit line 50, and a shield pattern 60 may be formed on the insulating material. Afterwards, the bit line insulating layer 56 may be formed by further depositing an insulating material to cover the shield pattern 60. The bit lines 50 may extend in the X-direction and may be spaced apart from each other in the Y-direction. The shield patterns 60 may extend in the X-direction and may be spaced apart from each other in the Y-direction. The shield patterns 60 may be arranged alternately with the bit lines 50 in the Y-direction.

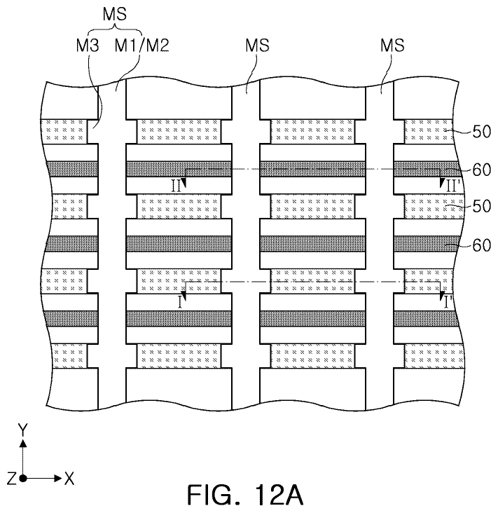

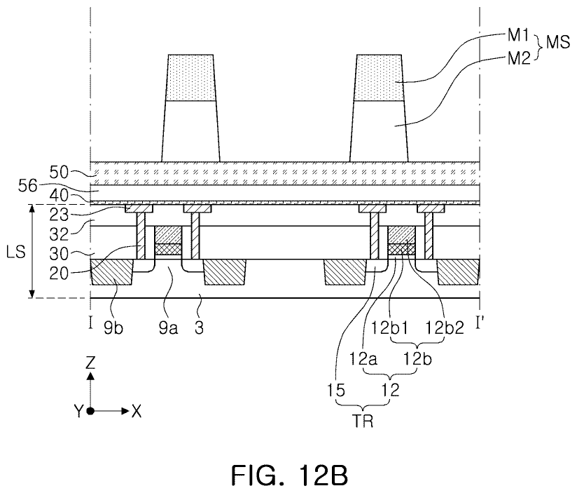

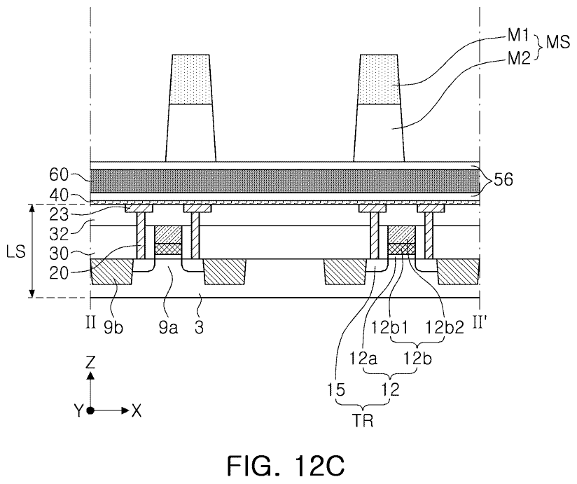

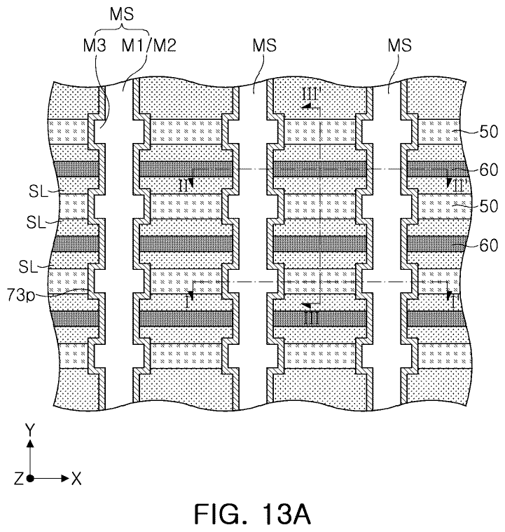

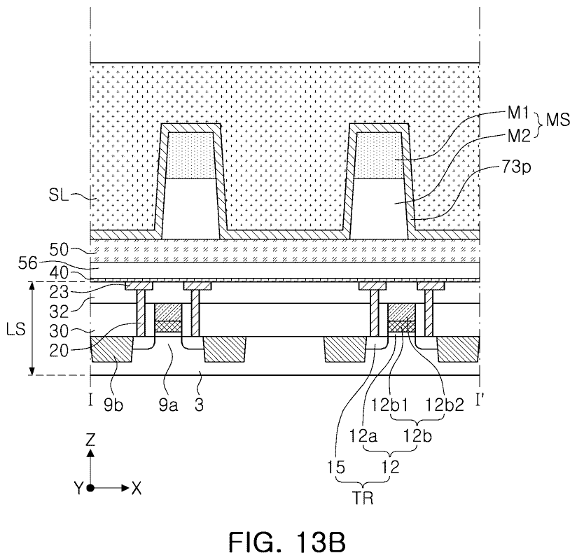

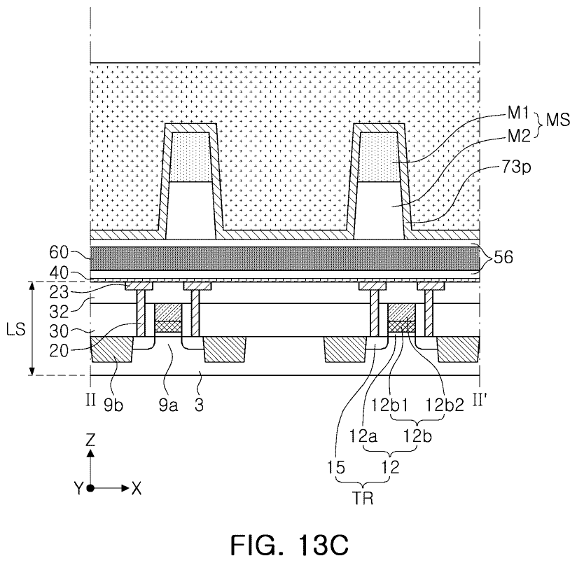

Referring to FIGS. 12A to 12C, a mold structure MS may be formed on the bit line 50 and the bit line insulating layer 56. After sequentially stacking the lower insulating material and the upper insulating material to cover the bit line 50 and the bit line insulating layer 56, the lower insulating material and the upper insulating material may be patterned to form a lower mold layer M2 and an upper mold layer M1.

The lower insulating material and the upper insulating material may be patterned to include a protrusion M3. For example, the protrusions M3 may protrude in the X-direction from both sides of the mold structure MS. For example, the protrusions M3 may be spaced apart from each other in the X and Y-directions, and may be disposed with the lower mold layer M2 and the upper mold layer M1 between them.

The mold structures MS may extend in the Y-direction and may be spaced apart from each other in the X-direction. In an example embodiment, the mold structure MS may have a tapered shape in which the horizontal width in the X-direction decreases upward, but is not limited thereto.

In an example embodiment, the lower mold layer M2 and the upper mold layer M1 may include different materials. For example, the lower mold layer M2 may include silicon oxide, and the upper mold layer M1 may include silicon nitride. In some embodiments, the lower mold layer M2 and the upper mold layer M1 may include the same material and may be formed integrally.

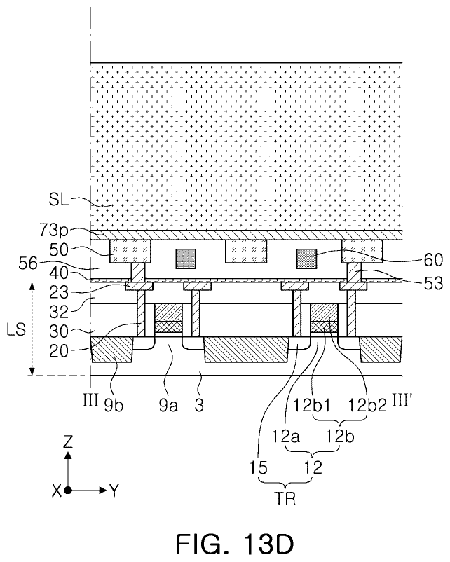

Referring to FIGS. 13A to 13D, a channel material layer 73p and a sacrificial layer SL may be formed. The channel material layer 73p may be formed to cover the bit line 50, the bit line insulating layer 56, and the mold structure MS. For example, the channel material layer 73p may conformally cover the mold structure MS. The sacrificial layer SL may be formed to cover the channel material layer 73p.

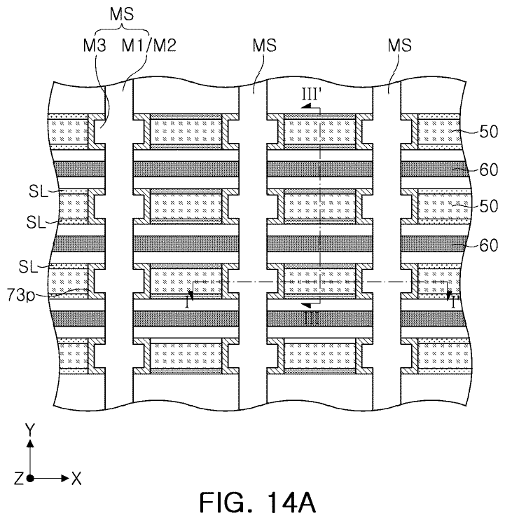

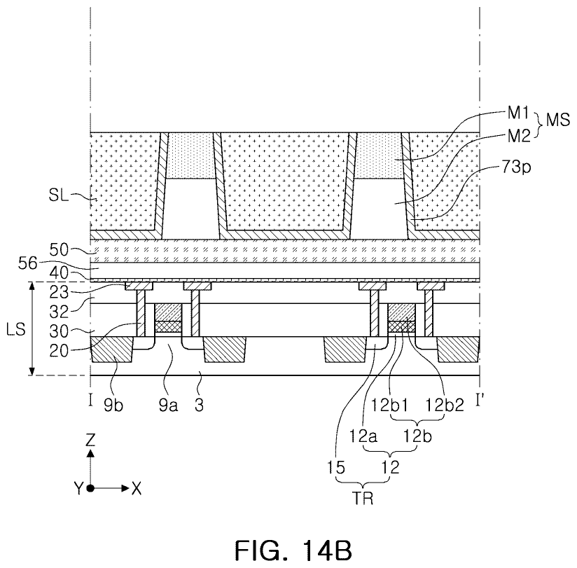

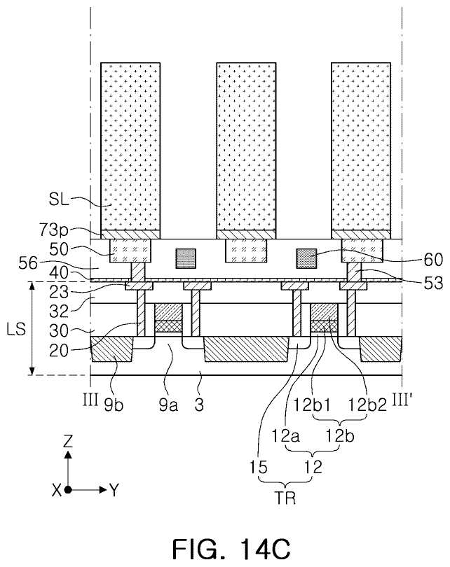

Referring to FIGS. 14A to 14C, the upper mold layer M1, the channel material layer 73p, and the sacrificial layer SL may be planarized and patterned. The channel material layer 73p and the sacrificial layer SL may be flattened so that the upper surface of the mold structure MS is exposed, and the upper surface of the channel material layer 73p and the upper surface of the sacrificial layer SL may be coplanar with the upper surface of the mold structure MS.

Additionally, the channel material layer 73p and the sacrificial layer SL may be patterned through an anisotropic etching process, and the upper surface of the bit line insulating layer 56 may be partially exposed. The patterned channel material layers 73p may extend in the X-direction between the mold structures MS and may be spaced apart from each other in the Y-direction.

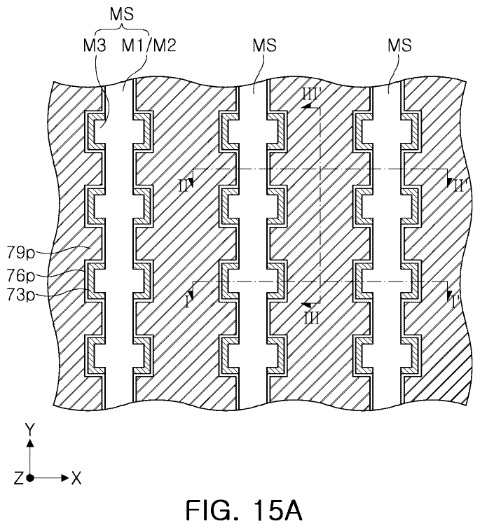

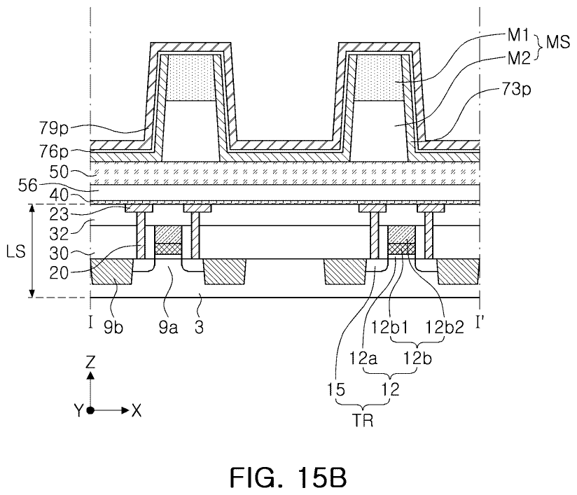

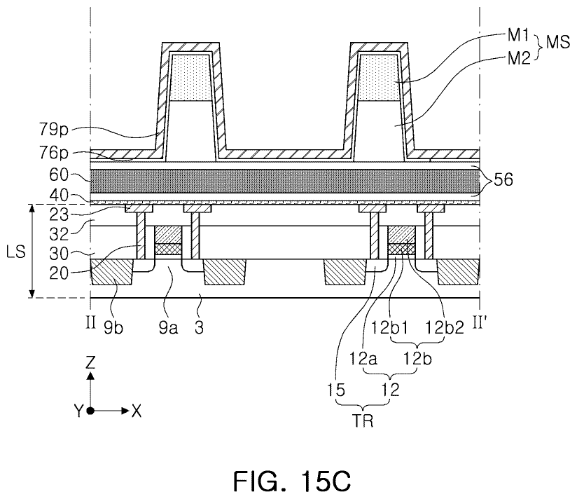

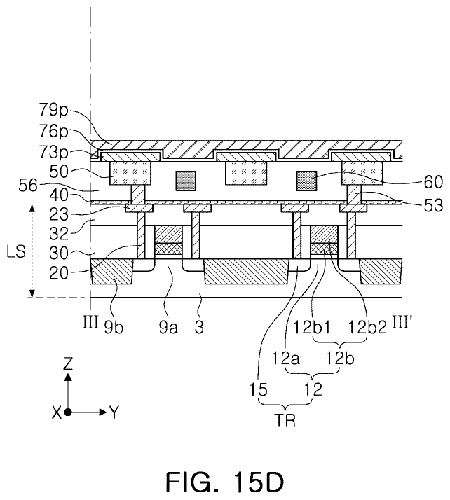

Referring to FIGS. 15A to 15D, the sacrificial layer SL may be removed, and a dielectric material layer 76p and a conductive layer 79p may be formed. The dielectric material layer 76p may be formed conformally on the bit line insulating layer 56, the channel material layer 73p, and the mold structure MS. The conductive layer 79p may cover the dielectric material layer 76p.

Referring again to FIGS. 1A to 1D, the dielectric material layer 76p and the conductive layer 79p may be etched through an anisotropic etching process to form the dielectric structure 76 and gate electrodes 79. In an example embodiment, a portion of the dielectric structure 76 covering the upper surface of the mold structure MS may remain without being removed, but is not limited thereto. In some embodiments, a portion of the dielectric structure 76 covering the upper surface of the mold structure MS may be removed, and the upper surface of the mold structure MS may be exposed.

In plan view, gate electrodes 79 may intersect bit lines 50. For example, the gate electrodes 79 may be disposed on the side of the mold structure MS, extend in the Y-direction, and be spaced apart from each other in the X-direction.

In an example embodiment, the channel structure 73 may be formed by etching a portion of the channel material layer 73p between the mold structures MS. The channel structure 73 may include a horizontal portion 73L that contacts the bit line 50 and extends in the horizontal direction, and a vertical channel portion 73S that extends upward from one end of the horizontal portion 73L. In an example embodiment, the vertical channel portion 73S may extend in a direction oblique to the vertical direction (Z-direction), but is not limited thereto. In some embodiments, vertical channel portion 73S may extend in a vertical direction. A portion of the channel material layer 73p may be etched to partially expose the upper surface of the bit line 50 between the mold structures MS. In some embodiments, the channel structure 73 may extend uninterrupted between adjacent mold structures MS in the X-direction.

An upper insulating structure 81 and an upper capping layer 82 may be formed. The upper insulating structure 81 may be formed by depositing an insulating material to cover the channel structure 73, the dielectric structure 76, and the gate electrodes 79, and then planarizing the insulating material. The upper insulating structures 81 may extend in the Y-direction and may be spaced apart from each other in the X-direction. The upper insulating structures 81 may be alternately arranged in the X-direction with the mold structures MS. The upper capping layer 82 may cover the upper surface of the upper insulating structure 81.

An opening exposing the channel structure 73 may be formed in the upper capping layer 82 through an anisotropic etching process, and a conductive material may be formed within the opening. Afterwards, the landing pad structure 83 may be formed by patterning the conductive material. The landing pad structure 83 is in contact with the channel structure 73 and may be electrically connected to the bit line 50 through the channel structure 73.

After depositing an insulating material to cover the landing pad structure 83, the insulating material may be flattened to expose the upper surface of the landing pad structure 83 to form an insulating pattern 86. The insulating pattern 86 may be disposed at the same level as the landing pad structures 83 and electrically insulate the landing pad structures 83 from each other. The mold structure MS, the channel structure 73, the dielectric structure 76, the gate electrode 79, the upper insulating structure 81, the upper capping layer 82, the landing pad structure 83, and the insulating pattern 86 may form the upper structure US.

Afterwards, a heating process may be performed. Through the heating process, the channel structure 73 may receive oxygen from the lower mold layer M2 containing silicon oxide. Therefore, oxygen vacancy in the channel structure 73 including the oxide semiconductor layer may be reduced, and cell active leakage current (Ioff) may be reduced and/or prevented. For example, when the cell transistor is not in operation, the cell active leakage current is reduced, and when a voltage is applied to the gate electrode 79 and the cell transistor is in operation, current may flow in the channel structure 73. The switching characteristics of the semiconductor device 100 may be improved. In addition, according to example embodiments, the vertical channel portion 73S of the channel structure 73 is arranged to overlap the mold structure MS in the Y-direction, and three sides of the channel portion 73S may be in contact with the mold structure MS. Accordingly, the contact area between the channel portion 73S and the mold structure MS may be increased without increasing the size of the semiconductor device 100. In addition, by increasing the contact area, oxygen vacancies may be more effectively reduced by the heating process, and cell active leakage current may be further reduced.

As set forth above, according to example embodiments, a vertical channel portion of a channel structure is in contact with the protrusion or recess of a mold structure, and thus the contact area between the channel structure and the mold structure may be increased. Therefore, oxygen vacancies in the channel structure may be more effectively reduced by a heating process, and cell active leakage current may be reduced and/or prevented.

While example embodiments have been illustrated and described above, it will be apparent to those skilled in the art that modifications and variations could be made without departing from the scope of inventive concepts as defined by the appended claims.

What is claimed is:

1. A semiconductor device comprising:
a bit line extending in a first horizontal direction;
a mold structure on the bit line;
a channel structure including a horizontal portion in contact with an upper surface of the bit line and a vertical channel portion extending upwardly from one end of the horizontal portion;
a gate electrode on the channel structure; and
a landing pad structure on the vertical channel portion and electrically connected to the channel structure, wherein
the vertical channel portion is in contact with a side surface of the mold structure,
at least a portion of the vertical channel portion overlaps the mold structure in a second horizontal direction, and
the second horizontal direction intersects the first horizontal direction.

2. The semiconductor device of claim 1, wherein
the mold structure includes a protrusion extending from a side surface of the mold structure in the first horizontal direction, and
the vertical channel portion overlaps the protrusion in the second horizontal direction.

3. The semiconductor device of claim 2, wherein the vertical channel portion surrounds an outer side surface of the protrusion.

4. The semiconductor device of claim 1, wherein
the vertical channel portion includes a first portion and a second portion,
the first portion is in contact with the mold structure in the first horizontal direction,
the second portion extends from the first portion and is curved, and
the second portion is in contact with the mold structure in the second horizontal direction.

5. The semiconductor device of claim 2, wherein
a horizontal width of the protrusion in the second horizontal direction decreases away from a central axis of the mold structure extending in the second horizontal direction.

6. The semiconductor device of claim 2, wherein, in plan view, the protrusion has a trapezoidal shape.

7. The semiconductor device of claim 2, wherein
the vertical channel portion includes an extension portion extending in the second horizontal direction, a first bent portion, and a second bent portion,
the first bent portion and the second bent portion extend from different sides of the extension portion, respectively, and
the first bent portion and the second bent portion each respectively extend in directions different than the second horizontal direction.

8. The semiconductor device of claim 7, wherein
the vertical channel portion further includes a first end and a second end extending in the second horizontal direction,
the first end is connected to the first bent portion, and
the second end is connected to the second bent portion.

9. The semiconductor device of claim 1, wherein
the mold structure includes a recess portion on a side surface of the mold structure, and
at least a portion of the vertical channel portion is within the recess portion.

10. The semiconductor device of claim 9, wherein a portion of the vertical channel portion protrudes from a side surface of the mold structure in the first horizontal direction.

11. The semiconductor device of claim 9, wherein the vertical channel portion completely fills the recess portion.

12. The semiconductor device of claim 9, further comprising:
a dielectric structure between the channel structure and the gate electrode, wherein
a portion of the dielectric structure is within the recess portion.

13. The semiconductor device of claim 9, wherein
ends of the vertical channel portion includes are in contact with the side surface of the mold structure, and
the ends of the vertical channel portion extend along the side surface of the mold structure in the second horizontal direction.

14. A semiconductor device comprising:
a bit line extending in a first horizontal direction;
a mold structure on the bit line and extending in a second horizontal direction, the second horizontal direction intersecting the first horizontal direction;
channel structures including horizontal portions in contact with an upper surface of the bit line and vertical channel portions extending upwardly from one ends of the horizontal portions;
a gate electrode on the channel structures; and
landing pad structures on the vertical channel portions and electrically connected to the channel structures, wherein
the mold structure includes first portions and second portions alternately disposed in the second horizontal direction,
lower surfaces of the first portions of the mold structure have a first horizontal width in the first horizontal direction,
lower surfaces of the second portions of the mold structure have a second horizontal width in the first horizontal direction,
the second width is different from the first horizontal width,
the vertical channel portions are spaced apart from each other in the second horizontal direction, and
the vertical channel portions contact a side surface of the mold structure.

15. The semiconductor device of claim 14, wherein
the second horizontal width is greater than the first horizontal width, and
the vertical channel portions respectively surround side surfaces of the second portions of the mold structure.

16. The semiconductor device of claim 15, wherein the vertical channel portions partially contact side surfaces of the first portions of the mold structure.

17. The semiconductor device of claim 14, wherein a distance between the vertical channel portions is less than a distance between the second portions of the mold structure.

18. The semiconductor device of claim 14, wherein
the vertical channel portions respectively include a first side surface, a second side surface, and a third side surface
the second side surface and the third side surface are connected to different sides of the first side surface, and
the first side surface, the second side surface, and the third side surface are in contact with the side surface of the mold structure.

19. The semiconductor device of claim 14, wherein
the second horizontal width is less than the first horizontal width,
the vertical channel portions respectively contact side surfaces of the second portions of the mold structure, and
the vertical channel portions respectively overlap the first portions of the mold structure in the second horizontal direction.

20. A semiconductor device comprising:
a lower structure including a circuit element;
a bit line on the lower structure and extending in a first horizontal direction;
a mold structure on the bit line and extending in a second horizontal direction, intersecting the first horizontal direction;
channel structures including horizontal portions in contact with an upper surface of the bit line and vertical channel portions extending upwardly from one ends of the horizontal portions;
a gate electrode on the channel structures;
a dielectric structure extending between the channel structures and the gate electrode in the second horizontal direction;
an upper insulating structure spaced apart from the mold structure and covering the gate electrode and the bit line;
an upper capping layer covering the mold structure and the upper insulating structure;
landing pad structures penetrating through the upper capping layer and electrically connecting to the channel structures; and
an information storage structure on the landing pad structures, wherein
the vertical channel portions contact a side surface of the mold structure, and
at least a portion of the vertical channel portions overlaps the mold structure in the second horizontal direction.
